(19) United States
(12) Patent Application Publication
(10) Pub. No.: US 2007/0148940 A1
(43) Pub. Date: Jun. 28, 2007

(54) Method for manufacturing a semiconductor device

(75) Inventor: Jae Won Han, Suwon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/642,758

(22) Filed: Dec. 21, 2006

(30) Foreign Application Priority Data
Dec. 28, 2005 (KR) 10-2005-132005

(51) Int. Cl. H01L 21/4763; H01L 21/3205

(52) U.S. Cl. 438/592

(57) ABSTRACT

Provided is a method for manufacturing a semiconductor device. In the method, a gate is formed in an active region of a substrate with a gate insulation layer interposed between the gate and the substrate. Spacers are formed on lateral sides of the gate. A first metal layer is deposited on an entire surface of the substrate. A photoresist pattern is formed to expose a region including at least the gate. A second metal layer is deposited on an entire surface of the substrate including the photoresist pattern. The photoresist pattern and a portion of the second metal layer formed on the photoresist pattern are removed. Silicides are formed in the gate and in an interface between the substrate and the first metal layer using heat treatment.

### RELATED APPLICATION

This application is based upon and claims the benefit of priority to Korean Application No. 10-2005-132005, filed on Dec. 28, 2005, the entire contents of which are incorporated herein by reference.

### BACKGROUND

1. Technical Field

The present invention relates to a method for manufacturing a semiconductor device.

2. Description of the Related Art

As semiconductor devices become smaller with advances in technology, the reduced size of silicon gates may generate many problems. In order to solve these problems, a method for forming a gate using a metal has been suggested.

However, when a metal gate of TiN, TaN or TiSiN is used, there is a problem that work functions of an N-channel metal oxide semiconductor (NMOS) and a P-channel metal oxide semiconductor (PMOS) are not changed.

Thus, a fully silicided (FUSI) gate obtained by forming a silicide in an entire gate is proposed as an alternative. The FUSI gate can offset the disadvantages of a metal gate because a work function thereof varies in a similar range to general polysilicon depending on implanted impurity ions. Further, the FUSI gate shows better performance than that of a general metal gate because a silicide is formed in an entire gate compared to a general metal gate, where a silicide is formed only on a surface of polysilicon.

However, the FUSI gate has a problem of causing junction leakage because silicides are formed too deep within the source and drain regions.

These problems can be solved by forming silicon in a region where a source and a gate is to be formed through selective epitaxial growth, implanting impurities, and forming a silicide. However, when the process is complicated, an additional chemical mechanical polishing (CMP) step is required. The CMP step may cause scratches, residues and other issues, resulting in deterioration of the semiconductor device.

### BRIEF SUMMARY

Accordingly, consistent with the present invention there is provided a method for manufacturing a semiconductor device that substantially obviates one or more problems due to limitations and disadvantages of the related art.

Moreover, the present invention provides a semiconductor device including a thick metal layer formed in a gate and thin metal layers formed in source and drain regions of a semiconductor substrate, and a method for manufacturing the same.

Additional advantages and features consistent with the invention will be set forth in part in the description which follows and in part will become apparent to those having ordinary skill in the art upon examination of the following. Other advantages consistent with the invention may be realized and attained by the structure pointed out in the written description and claims hereof as well as the appended drawings.

Consistent with the invention, as embodied and broadly described herein, there is provided a method for manufacturing a semiconductor device, the method including forming a gate in an active region of a substrate with a gate insulation layer interposed between the gate and the substrate, forming spacers on lateral sides of the gate, depositing a first metal layer on an entire surface of the substrate, forming a photoresist pattern such that a region including at least the gate is exposed, depositing a second metal layer on an entire surface of the substrate including the photoresist pattern, removing the photoresist pattern and a portion of the second metal layer formed on the photoresist pattern, and forming silicides in the gate and in an interface between the substrate and the first metal layer using heat treatment.

In another aspect consistent with the present invention, there is provided a semiconductor device including a gate formed on a substrate with a gate insulation layer interposed between the gate and the substrate, spacers formed on lateral sides of the gate, silicides formed in source and drain regions of the substrate through a reaction of the substrate with a first metal layer, and a silicide formed in the gate through a reaction of the gate with the first metal layer and a second metal layer.

Both the foregoing general description and the following detailed description of the present invention are exemplary and explanatory and are intended to provide further explanation consistent with the invention as claimed.

### BRIEF DESCRIPTION OF THE DRAWINGS

The accompanying drawings, which are included to provide further understanding consistent with the invention are incorporated in and constitute part of this application. These drawings illustrate embodiment(s) consistent with the invention and together with the description serve to explain the principle consistent with the invention. In the drawings:

FIGS. 1A to 1G are cross-sectional views illustrating a method for manufacturing a semiconductor device according to an embodiment consistent with the present invention.

### DETAILED DESCRIPTION OF THE INVENTION

Reference will now be made in detail to the preferred embodiments consistent with the present invention, examples of which are illustrated in the accompanying drawings.

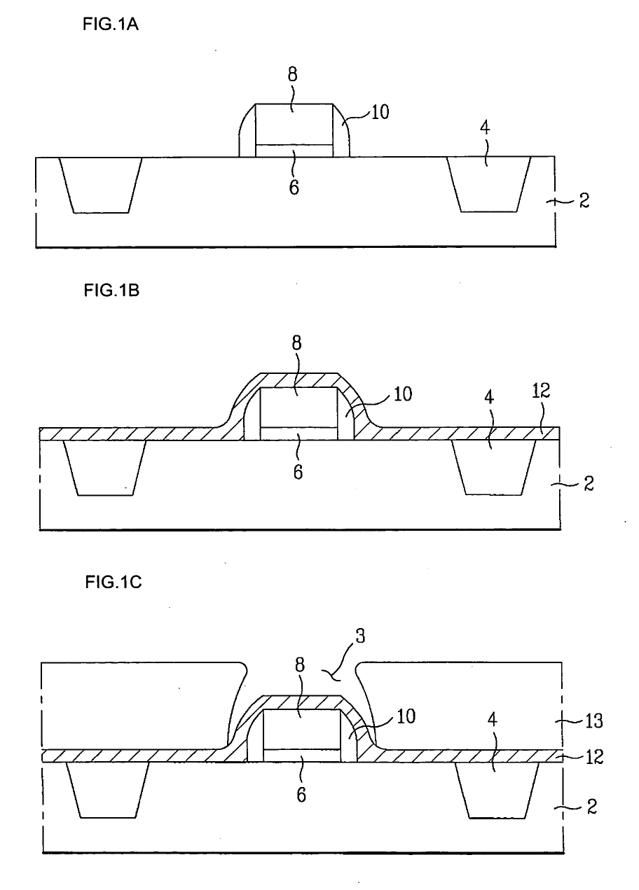

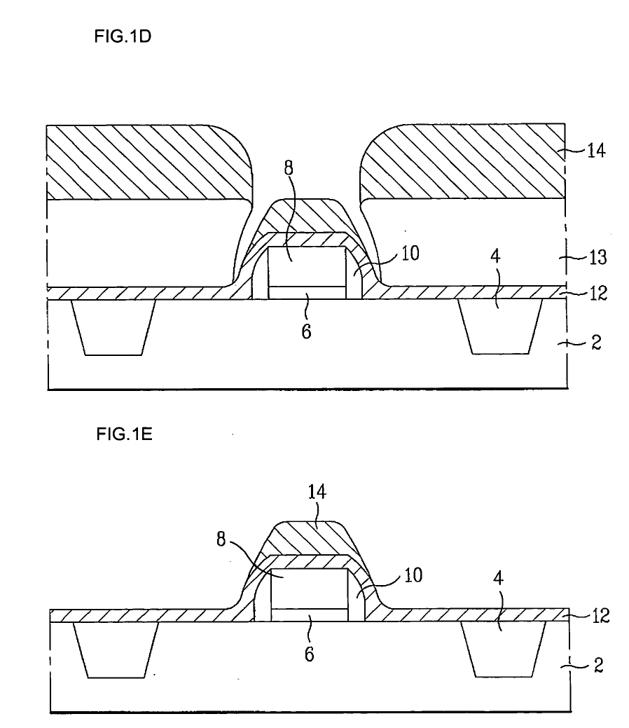

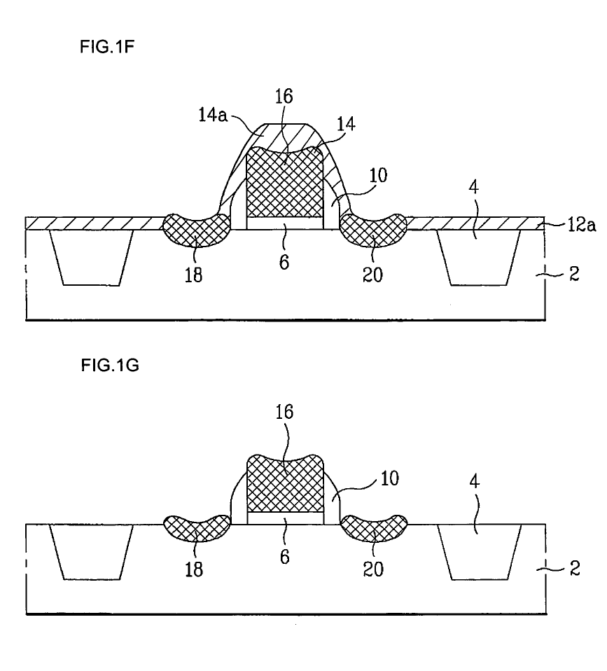

FIGS. 1A to 1G are cross sectional views illustrating a method for manufacturing a semiconductor device according to an embodiment consistent with the present invention.

Referring to FIG. 1A, a device isolation layer 4 is formed in a semiconductor substrate 2 to define a device isolation region and an active region. A gate 8 is formed on the active region of semiconductor substrate 2 with a gate insulation layer 6 interposed between gate 8 and semiconductor substrate 2. A spacer 10 is formed on a sidewall of gate 8 on semiconductor substrate 2.

Referring to FIG. 1B, a first metal layer 12 is deposited on an entire surface of semiconductor substrate 2 including gate 8 and spacer 10. Here, first metal layer 12 is formed of one of Co, Ni, Ti and etc. in order to form a silicide in a subsequent process. A first metal layer 12 is formed to have a thickness of 10˜200 Å in order to prevent the silicide from being formed too deep in source and drain regions (not shown) of the substrate in subsequent processes.

Referring to FIG. 1C, a photoresist is coated on first metal layer 12 and patterned to expose a region including at least a top surface of gate 8, in order to form a photoresist pattern 13. Thus, an opening 3 wider than the width of gate 8 is formed in photoresist pattern 13.

According to an embodiment consistent with the present invention, surface hardening is performed on a surface of a photoresist pattern 13 using trichloroethylene, so that photoresist pattern 13 has an inverted slope. That is, a lower part of an opening 3 formed in the photoresist is wider than an upper part of opening 3. Thus opening 3 is formed such that the upper part of the opening is somewhat wider than the width of gate 8 and the lower part of the opening is somewhat wider than the combined widths of a gate 8 and a spacer 10.

Referring to FIG. 1D, a second metal layer 14 is deposited on photoresist pattern 13 using physical vapor deposition (PVD). A second metal layer 14 is formed both on photoresist pattern 13 and on gate 8 because of the inverted slope shape of photoresist pattern 13.

Second metal layer 14 is formed of one of Co, Ni and Ti in order to form a silicide in a subsequent process, which is the same as the case of first metal layer 12. Second metal layer 14 is deposited to have a thickness of ¼˜½ times the thickness of the gate to form a fully silicided (FUSI) gate.

Referring to FIG. 1E, photoresist pattern 13 and a portion of second metal layer 14 deposited on photoresist pattern 13 are removed, so that a portion of second metal layer 14 remains only on gate 8.

Referring to FIG. 1F, heat treatment is performed to form suicides in gate 8 and in an interface between the semiconductor substrate and the first metal layer. According to an embodiment consistent with the present invention, the heat treatment may be performed using a rapid thermal process for 10˜200 seconds at a temperature range of 400˜1000° C.

During the heat treatment, a thick silicide 16 is formed in gate 8 through a reaction of the gate with the thick second metal layer 14. Silicides 18 and 20 are formed thin in source and drain regions of a semiconductor substrate through a reaction of the semiconductor substrate with the thin first metal layer 12.

Referring to FIG. 1G, unsilicided portions 12a and 14a of the first and second metal layers are removed from semiconductor substrate 2.

After that, a second heat treatment may also be performed to stabilize the silicides thus formed. In that case, the second heat treatment may be performed using a rapid thermal process for about 5˜200 seconds at a temperature range of about 500˜1000° C.

It should be understood that the description of the preferred embodiment is merely illustrative and that it should not be taken in a limiting sense. For example, although a rapid thermal process is used to form a silicide according to an embodiment consistent with the present invention, the present invention is not limited thereto, but instead, a heat treatment in an electric furnace may also be used.

Consistent with the present invention the method has an advantage of reducing a junction leakage, because depths of silicides formed in source and drain regions are small.

In addition, the present invention also has advantages of providing a substantially simplified process and of preventing an occurrence of defects due to chemical mechanical polishing, because chemical mechanical polishing is not included in the present invention method.

It will be apparent to those skilled in the art that various modifications and variations can be made consistent with the present invention. Thus, it is intended that the present invention covers the modifications and variations thereof within the scope of the appended claims.

What is claimed is:

1. A method for manufacturing a semiconductor device, comprising:
forming a gate in an active region of a substrate with a gate insulation layer interposed between the gate and the substrate;
forming spacers on lateral sides of the gate;
depositing a first metal layer on an entire surface of the substrate;
forming a photoresist pattern such that a region including at least the gate is exposed;
depositing a second metal layer on an entire surface of the substrate including the photoresist pattern;
removing the photoresist pattern and a portion of the second metal layer formed on the photoresist pattern; and
forming silicides in the gate and in an interface between the substrate and the first metal layer using heat treatment.

2. The method according to claim 1, wherein the photoresist pattern is formed such that a region including at least the gate and the spacer is exposed.

3. The method according to claim 1, wherein forming the photoresist pattern comprises performing a surface hardening process on a surface of the photoresist pattern.

4. The method according to claim 3, wherein the surface hardening process is performed using trichloroethylene.

5. The method according to claim 1, wherein the photoresist pattern comprises an opening for exposing the gate therein, a lower part of the opening being wider than an upper part of the opening.

6. The method according to claim 5, wherein the opening is formed such that the upper part of the opening is somewhat wider than a width of the gate, and the lower part of the opening is somewhat wider than a combined width of the gate and one of the spacers.

7. The method according to claim 1, wherein the first metal layer and the second metal layer are formed of one of Co, Ni and Ti.

8. The method according to claim 1, wherein the first metal layer is formed to have a thickness of about 10˜200 Å.

9. The method according to claim 1, wherein the second metal layer is formed to have a thickness of about ¼˜½ times a thickness of the gate.

10. The method according to claim 1, wherein the second metal layer is formed using physical vapor deposition.

11. The method according to claim 1, wherein the heat treatment comprises of a rapid thermal process.

12. The method according to claim 11, wherein the rapid thermal process is performed for about 10˜200 seconds at a temperature range of about 400˜1000° C.

13. The method according to claim 1, further comprising removing unsilicided portions of the first and second metal layers after forming the silicides.

14. The method according to claim 13, further comprising performing a rapid thermal process for about 5˜200 seconds at a temperature range of about 500˜1000° C. to stabilize the silicides after removing the unsilicided portions.

15. A semiconductor device, comprising:
a gate formed on a substrate with a gate insulation layer interposed between the gate and the substrate;
spacers formed on lateral sides of the gate;
silicides formed in source and drain regions of the substrate through a reaction of the substrate with a first metal layer; and
a silicide formed in the gate through a reaction of the gate with the first metal layer and a second metal layer.

16. The semiconductor device according to claim 15, wherein the first and the second metal layers are formed of one of Co, Ni and Ti.
